(19) United States
(12) Patent Application Publication
(10) Pub. No.: US 2011/0117236 A1
(43) Pub. Date: May 19, 2011

(54) DIE AND METHOD FOR MANUFACTURING DIE

(75) Inventor: Kensuke UEMURA, Niigata (JP)

(73) Assignee: IBIDEN CO., LTD., Ogaki-shi (JP)

(21) Appl. No.: 13/011,628

(22) Filed: Jan. 21, 2011

Related U.S. Application Data
(63) Continuation of application No. PCT/JP2009/063011, filed on Jul. 20, 2009.

(30) Foreign Application Priority Data
Jul. 23, 2008 (JP) 2008-189636

(51) Int. Cl. B29C 47/12; C23C 16/02

(52) U.S. Cl. 425/461; 216/37

(57) ABSTRACT

A die includes abase body and a modified surface layer. The base body includes tungsten carbide particles bonded by a bonding phase. The modified surface layer includes tungsten carbide particles and a filling material filled among the tungsten carbide particles to bond the tungsten carbide particles to each other. The filling material comprises copper. The modified surface layer is formed on at least a part of a surface of the base body.

### CROSS-REFERENCE TO RELATED APPLICATIONS

The present application is a continuation application of International Application No. PCT/JP2009/063011, filed Jul. 20, 2009, which claims priority to Japanese Patent Application No. 2008-189636 filed Jul. 23, 2008, entitled “METHOD FOR MANUFACTURING DIE AND DIE”. The contents of these applications are incorporated herein by reference in their entirety.

### BACKGROUND OF THE INVENTION

### FIELD OF THE INVENTION

The present invention relates to a die and a method for manufacturing the die.

### DISCUSSION OF THE BACKGROUND

An exhaust gas cleaning filter is set in an engine exhaust system to purify an exhaust gas of a motor vehicle. In view of heat resistance and durability, a material using ceramic mainly including silicon carbide (SiC) is used as a material of the exhaust gas cleaning filter. The exhaust gas cleaning filter can be obtained by extrusion-molding a material mainly including silicon carbide and firing the extrusion-molded material.

At this time, a die made of a cemented carbide is used as a die used for extrusion-molding. This provides the die having excellent abrasion resistance, and enables to enhance manufacturing efficiency such as longer cycle of die exchange. A so-called thermal spraying method which makes a metal of a molten state collide with a surface of a cemented carbide is used in order to prevent falling of tungsten carbide particles in extrusion molding. See, for example, Kaneto Ishikawa, et al., “Construction of Friction/Abrasion Database in Die Material”, Model Engineer Meeting, 2004, Lecture Collected Papers No. 211, Jun., 2004, pp. 132 to 133. The contents of this part of this reference is incorporated herein by way of reference. Accordingly, it is enabled to forma superficial layer made of the metal on the surface of the tungsten carbide.

### SUMMARY OF THE INVENTION

According to one aspect of the present invention, a die includes a base body and a modified surface layer. The base body includes tungsten carbide particles bonded by a bonding phase. The modified surface layer includes tungsten carbide particles and a filling material filled among the tungsten carbide particles to bond the tungsten carbide particles to each other. The filling material comprises copper. The modified surface layer is formed on at least a part of a surface of the base body.

According to another aspect of the present invention, a method for manufacturing the above-mentioned die includes etching at least apart of a surface of a cemented carbide including tungsten carbide particles bonded by a bonding phase with acid to form an etched surface with a part of the bonding phase removed. Copper is gasified in a chamber of a pressure-reduced atmosphere in which the cemented carbide is disposed. Gasified copper is liquefied on the etched surface in the chamber to impregnate grain boundaries of the tungsten carbide particles with liquefied copper.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a sectional view of a vicinity of a modified surface layer of a cemented carbide in example 1;

FIG. 2 is a sectional view of a vicinity of a superficial layer of the cemented carbide in the example 1;

FIG. 3 is a sectional view of the cemented carbide of a vicinity of an etched surface after an etching step in the example 1;

FIG. 4 is a sectional view of tungsten carbide particles on which an oxide film is formed in the example 1;

FIG. 5 is a sectional view of the cemented carbide (die) in the example 1;

FIG. 6 is a sectional view of a slit and a supply hole formed in the cemented carbide (die) in the example 1;

FIG. 7 is an illustration of an electron beam irradiation device in the example 1;

FIG. 8 is an illustration of the cemented carbide and a peripheral member thereof loaded in the electron beam irradiation device in the example 1;

FIG. 9 is a SEM photograph in substitution for a drawing, showing a sectional view of a vicinity of the etched surface after etching with acid in the example 1;

FIG. 10 is a SEM photograph in substitution for a drawing, showing the etched surface after alkali treatment in the example 1;

FIG. 11 is a SEM photograph in substitution for a drawing, showing a sectional view of a vicinity of the modified surface layer after a copper impregnating step in the example 1;

FIG. 12 is an illustration for explaining a method of an abrasion and friction test in example 2;

FIG. 13 is a diagrammatic view showing measurement results of friction coefficients in the example 2;

FIG. 14A is a SEM photograph in substitution for a drawing, showing abrasive flaw of an indenter ball reciprocatably slid 1,000 times on a sample 1 in the example 2;

FIG. 14B is a SEM photograph in substitution for a drawing, showing the abrasive flaw of the indenter ball reciprocatably slid 20,000 times on the sample 1 in the example 2;

FIG. 14C is a SEM photograph in substitution for a drawing, showing the abrasive flaw of the indenter ball reciprocatably slid 1,000 times on a sample 2 in the example 2;

FIG. 14D is a SEM photograph in substitution for a drawing, showing the abrasive flaw of the indenter ball reciprocatably slid 20,000 times on the sample 2 in the example 2; and

FIGS. 15A and 15B are illustrations for explaining an abrasion mechanism of a surface of the cemented carbide caused by silicon carbide.

### DESCRIPTION OF THE EMBODIMENTS

The embodiments will now be described with reference to the accompanying drawings, wherein like reference numerals designate corresponding or identical elements throughout the various drawings.

A die made of a cemented carbide having excellent abrasion resistance is used as the die described above. However, a silicon carbide particle has extremely high hardness and has HV hardness of about 2500, which is higher than HV hardness (about 1800) of the die. Therefore, unfortunately, the abrasion of an inner wall of a slit for molding a ceramic material in the die by repeatedly extrusion molding cannot be sufficiently reduced without difficulty.

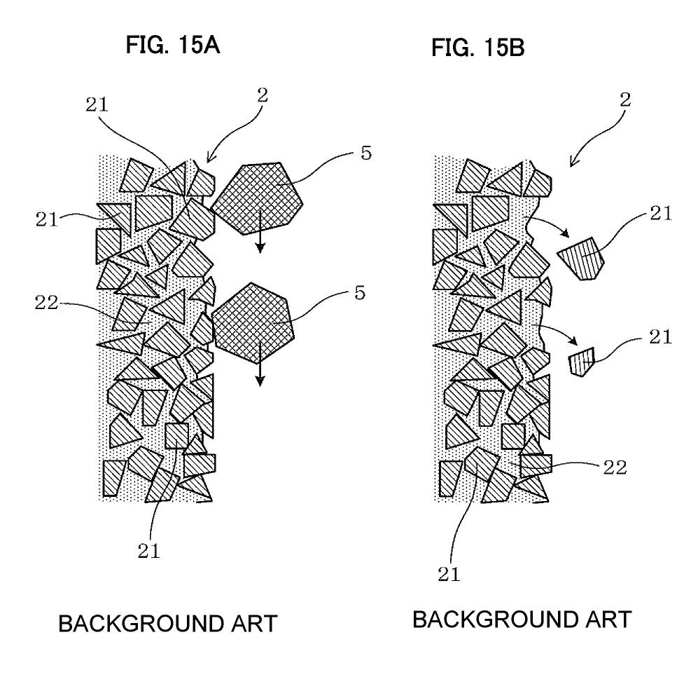

The mechanism of the abrasion of the cemented carbide is assumed to be based on falling of tungsten carbide (WC) particles constituting the cemented carbide with the flow of silicon carbide. That is, as shown in FIGS. 15(A) and 15(B), in a cemented carbide 2 including tungsten carbide particles 21 bonded by a bonding phase 22 made of cobalt (Co), it is assumed that the tungsten carbide particles 21 gradually fall off because SiC particles 5 collide with the tungsten carbide particles 21 exposed to the surface of the cemented carbide 2. As stated above, it is assumed that the abrasion of the cemented carbide 2 develops in this manner.

Since the superficial layer disclosed in Non-Patent Document 1 exists on the surface of each of the tungsten carbide particles, and is not necessarily penetrated among the particles, particularly, the application of the superficial layer to a die on which particles of silicon carbide having high hardness slide is not considered.

According to an embodiment of the present invention, a die having excellent abrasion resistance, and a method for manufacturing the die can be provided.

A first embodiment of the present invention provides a die includes a base body including tungsten carbide particles bonded by a bonding phase, and a modified surface layer including tungsten carbide particles and a filling material filled among the tungsten carbide particles to bond the tungsten carbide particles to each other, the filling material being mainly made of copper. The modified surface layer is formed on at least apart of a surface of the base body.

Next, effects of the embodiments of the present invention will be described.

The die of the first embodiment of the present invention is made of a cemented carbide including the tungsten carbide particles bonded by the bonding phase. The die has a surface having the modified surface layer. The modified surface layer is provided in at least a part of a superficial layer portion of the base body. Accordingly, this can prevent the tungsten carbide particles from falling without difficulty, and the die having excellent abrasion resistance can be easily obtained.

However, the copper itself is a material having low hardness. Therefore, the copper is not generally considered to be used as a binder in place of cobalt in the cemented carbide. The reason why such constitution as described above provides an abrasion resistant effect is believed that the copper (filling material) moderately receives an external force applied to the tungsten carbide particles provided in a superficial layer of the die; in other words, the filling material has viscosity. The constitution does not have a form in which the copper exists only on the surface as seen in the case of thermal spraying or the like, but has a form in which the copper (filling material) is filled among the tungsten carbide particles. Thereby, it is believed that the tungsten carbide particles can be sufficiently bonded with ease and effects of abrasion resistance can be exhibited.

As described above, according to the first embodiment of the present invention, it is enabled that the die having excellent abrasion resistance is provided.

A second embodiment of the present invention is a method for manufacturing the die according to the first embodiment of the invention. The method includes an etching step of etching with acid at least a part of a surface of a cemented carbide including tungsten carbide particles bonded by a bonding phase with acid to form an etched surface with a part of the bonding phase removed, a gasifying step of gasifying copper in a chamber of a pressure-reduced atmosphere in which the cemented carbide is provided, and a copper impregnating step of liquefying the gasified copper on the etched surface in the chamber to impregnate grain boundaries of the tungsten carbide particles with the liquefied copper.

In the method for manufacturing the die according to the second embodiment of the present invention, the copper is gasified in the copper impregnating step, and the gasified copper is supplied to the etched surface. The gasified copper is liquefied on the etched surface. The grain boundaries of the tungsten carbide particles are impregnated with the liquefied copper. That is, the gasified copper enters the fine grain boundaries formed among the tungsten carbide particles on the etched surface. The fine grain boundaries of the tungsten carbide particles are, by the capillary phenomenon, further impregnated with the copper liquefied on the etched surface.

It is enabled to set an equilibrium contact angle between fused oxygen-free copper and a tungsten carbide base material to about 0 degree (about ±5 degrees) by controlling an atmosphere under a fixed condition at this time. That is, the surface of each of the tungsten carbide particles easily get almost completely wet with the copper, and the grain boundaries can be easily impregnated with the copper. In the modified surface layer manufactured by the manufacturing method, the material mainly made of copper is sufficiently filled among the tungsten carbide particles. Accordingly, the tungsten carbide particles can be firmly bonded easily as described in the description of the first embodiment of the present invention.

As described above, according to the second embodiment of the present invention, it is enabled that the method for manufacturing the die having excellent abrasion resistance is provided.

In the first embodiment of the present invention, the modified surface layer may be formed on at least a portion with which a molding material molded by the die is brought into contact. The modified surface layer may be formed on a part of a surface of the base body, or may be formed on the whole surface thereof.

The depth of the modified surface layer is preferably equal to or greater than the average particle diameter of the tungsten carbide particles, and more preferably about 1 to about 10 μm.

In this case, the modified surface layer is sufficiently formed with ease. Thereby, the tungsten carbide particles can be easily fixed firmly to each other to effectively enhance abrasion resistance. When the depth of the modified surface layer is not less than the average particle diameter of the tungsten carbide particles, the thickness of the modified surface layer is less likely to be insufficient so that sufficient abrasion resistance can be obtained easily.

When the average particle diameter of the tungsten carbide particles is, for example, about 1 μm, the removal depth (the thickness of the modified surface layer) of the bonding phase is preferably equal to or more than about 1 μm. The removal depth (the thickness of the modified surface layer) is preferably equal to or less than about 10 μm. That is, when the removal depth (the thickness of the modified surface layer) is equal to or less than about 10 μm in the case where the average particle diameter of the tungsten carbide particles is about 1 μm, the tungsten carbide particles is less likely to fall off the surface of a cemented carbide in the handling that is performed after an etching step to be described later.

When a surface layer to be described later does not exist, the depth of the modified surface layer is a distance from a material sliding side surface to a deep part. When the surface layer exists, the depth of the modified surface layer is a distance between a top part of the tungsten carbide particle on a material sliding side and a deep part.

It is preferable that each of the tungsten carbide particles disposed in a superficial layer on a side opposite from the base body side in the modified surface layer has a surface located on the side opposite from the base body side, the surface being covered with a surface layer mainly made of copper.

In this case, the tungsten carbide particles begin to be abraded after the surface layer is scraped. Thereby, the abrasion resistance of the die can be further enhanced easily. The surface layer itself also has small surface roughness. The small surface roughness can further reduce friction caused by the particles sliding on the surface of the die to suppress intensive abrasion easily.

In the die, the thickness of the surface layer is preferably about 0.1 to about 10 μm. The thickness of the surface layer is a distance between the top part of the tungsten carbide particle on the material sliding side and the surface of the layer.

In this case, the effects caused by the surface layer can sufficiently be exhibited easily, and the abrasion of the die can be further suppressed easily.

The thickness of the surface layer is a distance between the top part of the tungsten carbide particle on the material sliding side and the surface of the layer.

When the thickness of the surface layer is equal to or more than about 0.1 μm, it becomes easy to sufficiently exhibit the effects caused by the surface layer. On the other hand, when the thickness of the surface layer is equal to or less than about 10 μm, the tungsten carbide particles exist between the surface of the die and a position of a depth of equal to or less than 10 μm from the surface. Thereby, the surface layer mainly made of copper becomes less likely to be abraded and to cause the dimensional change of the die.

The modified surface layer is preferably formed by bringing vaporized copper into contact with the surface of the die and making the copper penetrate among the tungsten carbide particles in a pressure-reduced atmosphere.

In this case, the copper easily penetrates among the tungsten carbide particles, and the modified surface layer can be easily and certainly formed.

The modified surface layer is preferably formed on at least a surface of the die on which a high hardness particle-containing material slides, to mold the high hardness particle-containing material including particles having hardness higher than that of the tungsten carbide particles.

In this case, the sufficient effects of the embodiment of the present invention can be easily exhibited. That is, as described above, prevention of abrasion is considered to be difficult for the die molding the high hardness particle-containing material, even if a conventional cemented carbide is used. Then, the formation of the modified surface layer on the surface on which the high hardness material slides enables the die having excellent abrasion resistance to be effectively provided easily.

The high hardness particle-containing material is preferably a paste containing silicon carbide particles.

In this case, since the silicon carbide particles have hardness higher than that of tungsten carbide particles, the effects of the embodiment of the present invention can be sufficiently exhibited easily.

It is preferable that the die is a die for extrusion-molding a honeycomb body having a plurality of cells separated by dividing walls, and has slits for molding the passed material to the dividing walls.

In this case, if the first embodiment of the present invention is not applied, the slit of the die becomes to be easily abraded by repeatedly casting the honeycomb body to cause the dimensional change of the slit easily. As a result, a dimensional error may easily occur in the thickness of the dividing wall of the honeycomb body to be molded. Then, the die having excellent abrasion resistance can be obtained by applying the first embodiment of the present invention to effectively suppress the occurrence of the dimensional error of the dividing wall with ease.

In the second embodiment of the present invention, it is preferable that the method further includes a step of removing an oxide attached to the tungsten carbide particles by treating the etched surface with an alkali solution between the etching step and the copper impregnating step.

In this case, the wettability of the copper to be impregnated in the copper impregnating step, to the tungsten carbide particles can be easily secured to sufficiently secure the collective strength of the tungsten carbide particles caused by the copper (filling material) with ease. Thereby, the falling of the tungsten carbide particles can be more certainly prevented to enhance the abrasion resistance of the die easily.

### EXAMPLES

### Example 1

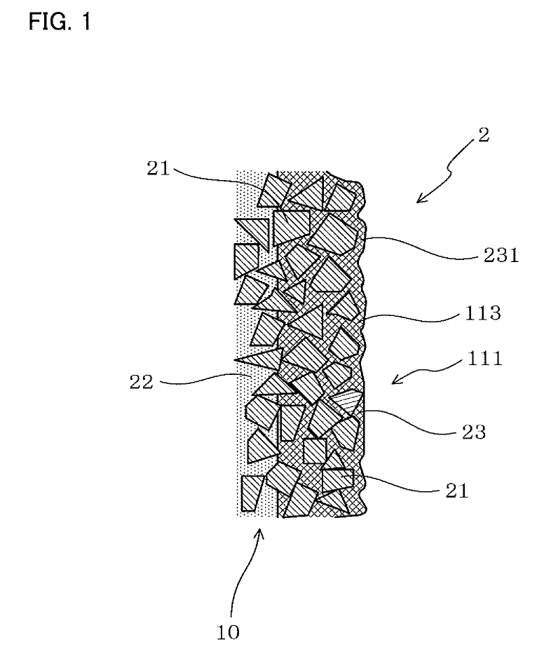

A method for manufacturing a die according to an example of the present invention and the die obtained by the method will be described with reference to FIGS. 1 to 11.

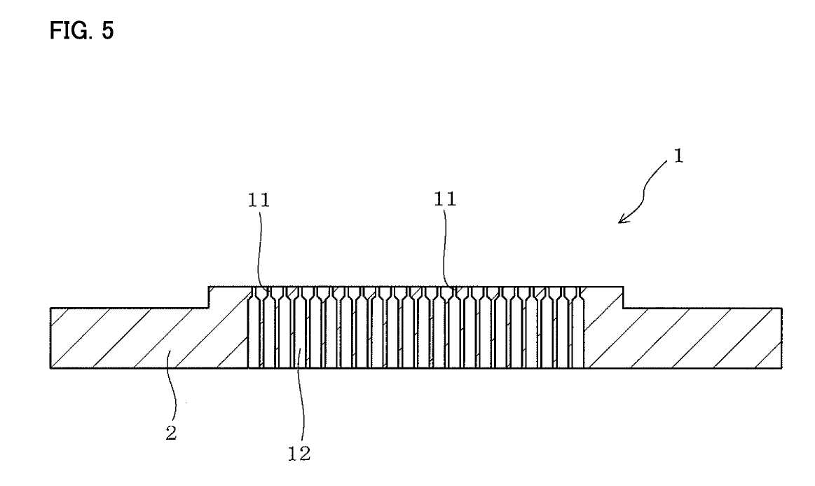

A method for manufacturing a die in the example is a method for manufacturing a die 1 (FIG. 5) for extrusion-molding an exhaust gas cleaning filter made of ceramic mainly including silicon carbide. The method has a processing step, an etching step, a gasifying step and a copper impregnating step, which will be shown below.

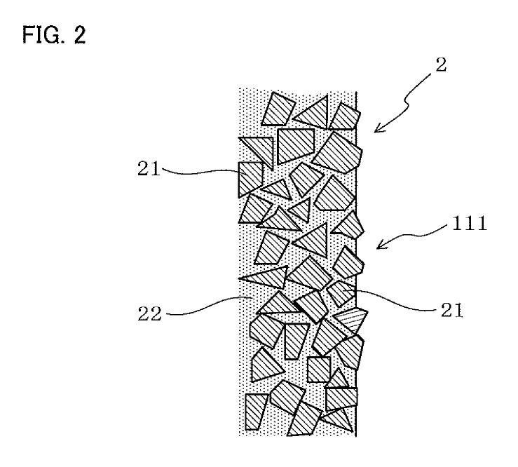

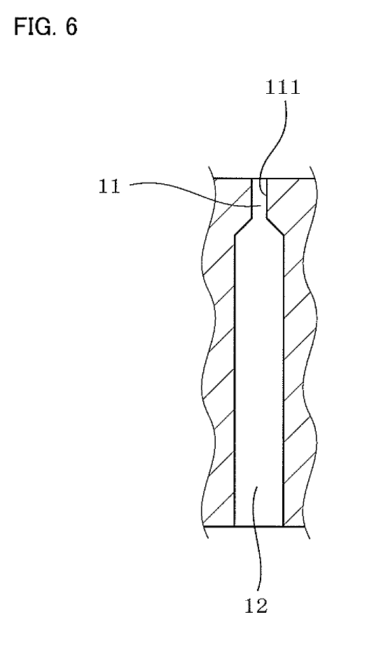

As shown in FIG. 2, a cemented carbide 2 includes tungsten carbide particles 21 bonded by a bonding phase 22 made of cobalt. As shown in FIGS. 5 and 6, the cemented carbide 2 is processed in the processing step to form slits 11 for molding dividing walls of an exhaust gas cleaning filter and supply holes 12 for supplying a material (paste) mainly including silicon carbide to the slits 11.

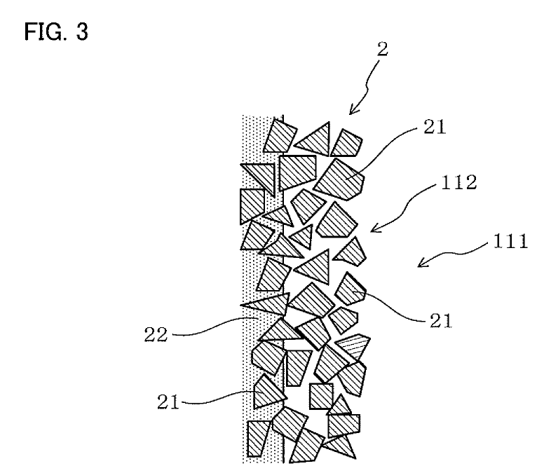

In the etching step, at least an inner side surface 111 of the slit 11 is then etched with acid to form an etched surface 112 with a part of a bonding phase 22 removed, as shown in FIG. 3.

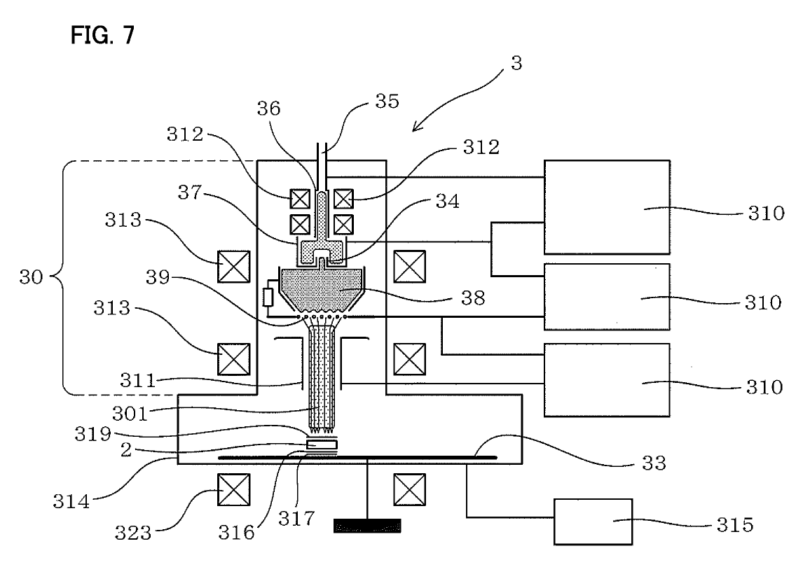

In the gasifying step, as shown in FIG. 7, a copper target 316 disposed with the cemented carbide 2 in a chamber 314 is then irradiated with an electron beam 301 to gasify the copper.

In the copper impregnating step, the gasified copper is liquefied on the etched surface 112 to impregnate grain boundaries of the tungsten carbide particles 21 with the liquefied copper.

Thereby, as shown in FIG. 1, a modified surface layer 113 including the tungsten carbide particles 21 bonded by copper 23 as a filling material is formed on the inner side surface 111 of the slit 11.

That is, the die 1 of the present example includes abase body 10 including the tungsten carbide particles 21 bonded by the bonding phase 22 made of cobalt and the modified surface layer 113 formed on a part of a surface of the base body 10. Each of the tungsten carbide particles 21 disposed in a superficial layer on a side opposite from the base body 10 side in the modified surface layer 113 has a surface located on the side opposite from the base body 10 side, the surface being covered with a surface layer 231 made of copper.

Hereinafter, detailed descriptions will be given of steps after the etching step of the method for manufacturing the die that has been actually carried out.

As shown in FIG. 2, the cemented carbide 2 is formed by bonding the tungsten carbide particles 21 by the bonding phase 22 made of cobalt. In the etching step, a surface including the inner side surface 111 of the slit 11 provided in the cemented carbide 2 was etched.

Strong acid was used as an etching solution. Such strong acid was prepared by diluting Fuji Aceclean (registered trade name) FE-17 manufactured by Fuji Acetylene Ind. Co., Ltd. with pure water so that a weight ratio of FE-17 to pure water was set to 1:3. A composition of Fuji Aceclean FE-17 is represented as HNO₃:HF:H₂O of 53.8:8.0:38.2 at a weight ratio.

The cemented carbide 2 was pickled by immersing the cemented carbide 2 in the etching solution for 400 seconds while an ultrasonic wave was applied to the cemented carbide 2, to form the etched surface 112. The cemented carbide 2 was then washed with pure water and was dried.

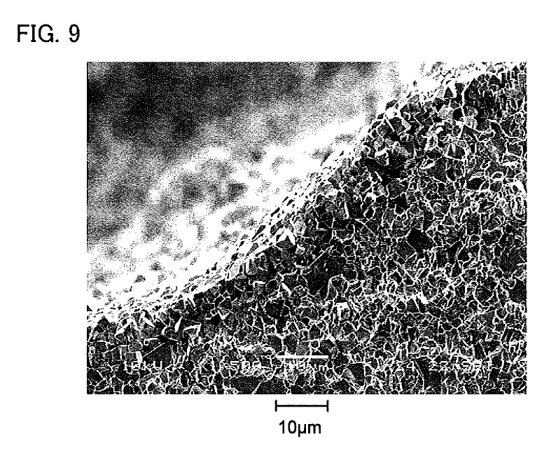

After the drying, as shown in FIG. 9, the section of the etched surface 112 was observed by SEM (scanning electron microscope). The removal depth of the bonding phase 22 was 5 to 7 μm.

Next, the etched surface 112 of the cemented carbide 2 was surface-treated with an alkali solution. That is, the cemented carbide was immersed in the alkali solution for 60 minutes while the ultrasonic wave was applied to the cemented carbide. The composition of the alkali solution contains 10% by weight of potassium hydroxide (KOH), 10% by weight of potassium ferricyanide (K₃[Fe(CN)₆]) and the balance of water (H₂O).

Then, the cemented carbide 2 was washed with pure water and was dried.

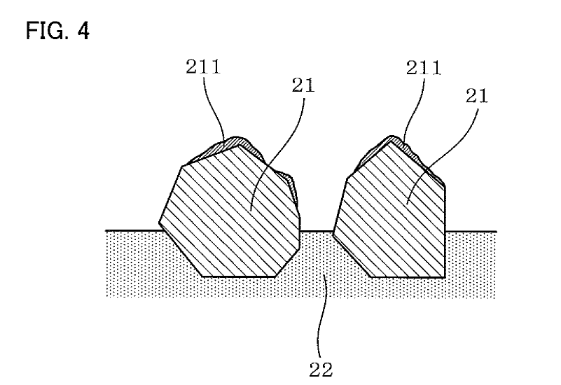

As shown in FIG. 4, the etched surface 112 is surface-treated with the alkali solution to remove a thin oxide film 211 formed on the surface of each of the tungsten carbide particles 21. That is, the oxide film 211 made of WO₃ or the like maybe formed on the surface of each of the exposed tungsten carbide particles 21. Then, the oxide film 211 is removed to enhance the wettability and adhesion of the copper 23 to be impregnated later and the tungsten carbide particles 21.

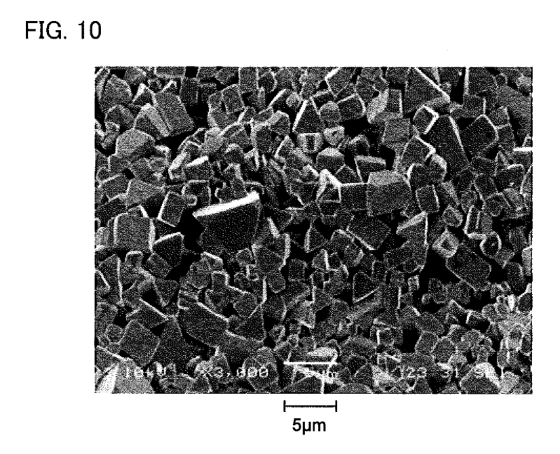

After alkali washing and drying, the etched surface 112 was observed by EDS. The observation could confirm that an oxygen component was sufficiently reduced. When, as shown in FIG. 10, the etched surface 112 was observed by SEM, falling of the tungsten carbide particles 21 was not observed. As the result of the observation using a magnifying lens, there was no problem with the dimensional tolerance of the cemented carbide 2.

Next, the gasifying step and the copper impregnating step were carried out. That is, the acid-washed and alkali-washed cemented carbide was loaded in an electron beam irradiation device 3 shown in FIG. 7.

The electron beam irradiation device 3 has a chamber 314 including a turntable 33 for placing the cemented carbide 2 and an irradiation source 30 of the electron beam 301 disposed above the turntable 33. A pump 315 for vacuum-sucking the inside of the chamber 314 is connected to the chamber 314.

The irradiation source 30 has a gas introducing part 35, a magnet 312, a hollow anode 36, a hollow cathode 37, a plasma generating part 38, a grid 39 and a drift tube 311. The gas introducing part 35 introduces an argon gas. The magnet 312 excites the introduced argon gas molecules. The hollow anode 36 and the hollow cathode 37 convey the argon molecules of an excitation state to the plasma generating part. The plasma generating part 38 converts the argon molecules into plasma. The grid 39 accelerates electrons in plasma in the plasma generating part 38 toward the copper target 316. The drift tube 311 conveys the electron beam 301 toward the copper target 316. The argon molecules are converted into plasma in the plasma generating part 38 by a pulse-like magnetic field caused by a magnet coil 313 provided around the plasma generating part 38.

A bundle of the electron beams 301 passing through the grid 39 is converged toward the copper target 316 by the magnetic field of a magnet coil 323 disposed below the chamber 314. Reference numeral 310 in FIG. 7 designates a power supply for applying a voltage to the hollow anode 36, the hollow cathode 37, the grid 39 and the drift tube 311.

The gasifying step and the copper impregnating step were carried out using the electron beam irradiation device 3.

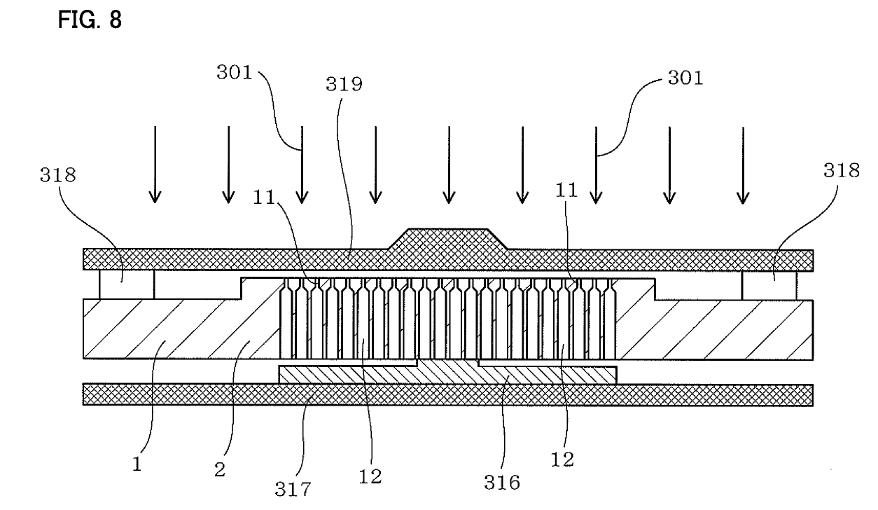

First, a receiving plate 317 made of graphite was disposed on the upper surface of the turntable 33. The copper target 316 was disposed on the upper surface of the receiving plate 317. The cemented carbide 2 was disposed thereon. A copper foil having a thickness of 0.05 mm was used as the copper target 316. As shown in FIG. 8, the copper target 316 had a size corresponding to a region in which the slits 11 and the supply holes 12 were formed in the cemented carbide 2. The copper target 316 was disposed so as to correspond to the region. That is, the copper target 316 was disposed below the forming region of the supply holes 12.

A buffer plate 319 made of graphite was disposed on spacers 318 disposed on the cemented carbide 2.

In this state, the inside of the chamber 314 was vacuum-sucked to about 10⁻³ Pa. The copper target 316 was then irradiated with the pulse-like electron beam 301 from the irradiation source 30 while the turntable 33 was rotated at a speed of 15 rpm. The copper target 316 was irradiated with 10000 pulses of the electron beam 301 at a beam current value of 100 A, an accelerating voltage of 20 kV, a pulse width of 200 μs and a frequency of 10 Hz. At this time, the irradiation time was 16 minutes and 40 seconds, and the average required power was 4 kW.

As described above, the copper target 316 is irradiated with the electron beam 301 to gasify the copper of the copper target 316. The gasified copper passes through the supply holes 12 in the cemented carbide 2 and reaches the inner side surfaces 111 of the slits 11. The gasified copper is liquefied on the etched surface 112 formed on the inner side surface 111, and the grain boundaries of the tungsten carbide particles 21 are impregnated with the gasified copper.

Thereby, the modified surface layer 113 including the tungsten carbide particles 21 bonded by the copper 23 was formed on the inner side surface 111 of the slit 11.

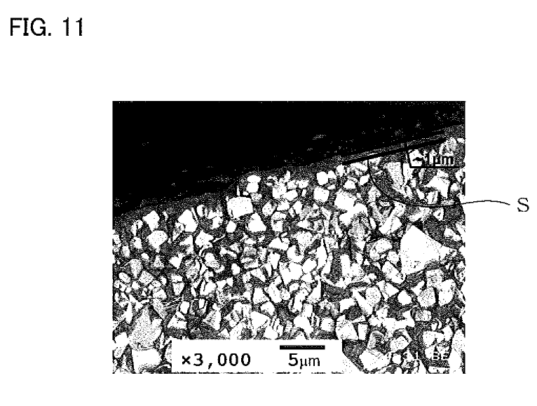

After the irradiation of the electron beam, as shown in FIG. 11, the section of the modified surface layer 113 was observed by SEM. As a result, a portion from which the bonding phase 22 made of cobalt was removed was almost completely filled with the copper 23, so no pore remained there. The copper 23 in the modified surface layer 113 was not only filled into the grain boundaries of the tungsten carbide particles 21 but also deposited on a plane S on which the tungsten carbide particles 21 exist by a thickness of 0.3 to 0.5 μm.

Next, effects of the example will be described.

The method for manufacturing the die has the gasifying step and the copper impregnating step. The method gasifies the copper, and supplies the gasified copper to the etched surface 112. The method liquefies the gasified copper on the etched surface 112, and impregnates the grain boundaries of the tungsten carbide particles 21 with the liquefied copper. That is, the fine grain boundaries among the tungsten carbide particles 21 formed on the etched surface 112 are impregnated with the gasified copper. The fine grain boundaries of the tungsten carbide particles 21 are further impregnated with the copper liquefied on the etched surface 112 by the capillary phenomenon. As shown in FIG. 1, it becomes possible to form the modified surface layer 113 including the tungsten carbide particles 21 bonded by the copper 23 on the surface of the cemented carbide 2, that is, on at least the inner side surface 111 of the slit 11 by the solidification of the copper.

As described above, the modified surface layer 113 has excellent abrasion resistance. Therefore, even when a ceramic material mainly including silicon carbide repeatedly passes through the slit 11, the abrasion caused by the repeated passing can be suppressed easily, and the die 1 having longer service life can be obtained easily.

As shown in FIG. 8, the buffer plate 319 is disposed between the irradiation source 30 of the electron beam 301 and the cemented carbide 2 so as to prevent the direct irradiation of the cemented carbide 2 with the electron beam 301 and easily to alleviate impact on the cemented carbide 2. Thereby, the possibility of damaging the cemented carbide 2 can be easily prevented.

The oxide (the oxide film 211) attached to the tungsten carbide particles 21 is removed by treating the etched surface 112 with the alkali solution between the etching step and the copper impregnating step. Thereby, the wettability of the copper 23, which is impregnated in the copper impregnating step, to the tungsten carbide particles 21 can be easily secured to sufficiently secure the bonding strength of the tungsten carbide particles 21 caused by the copper 23 with ease. Therefore, the falling of the tungsten carbide particles 21 can be more certainly prevented to enhance the abrasion resistance of the die 1 easily.

Since the removal depth of the bonding phase 22 in the etching step is about 5 to about 7 μm, the modified surface layer 113 is sufficiently formed, and it becomes easier to effectively enhance the abrasion resistance.

As described above, the example enables the method for manufacturing the die having excellent abrasion resistance and the die to be provided.

### Example 2

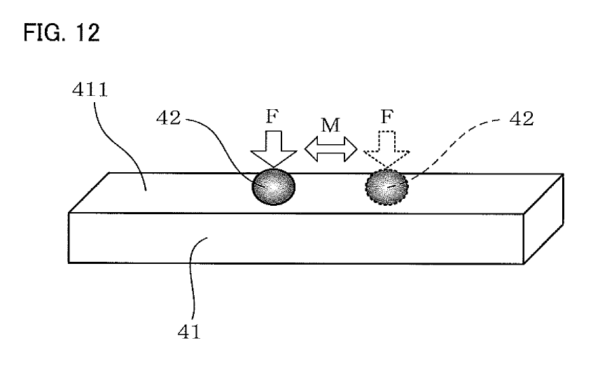

The present example is an example in which an abrasion and friction test of a cemented carbide 2 is carried out to confirm effects of the embodiment of the present invention as shown in FIGS. 12 to 14.

First, a modified surface layer 113 was formed on the surface of the cemented carbide 2 by the same method as in the example 1. At this time, as shown in FIG. 12, the cemented carbide 2 was formed as a planar specimen 41 having a flat surface 411, instead of the die 1 shown in the example 1. The modified surface layer 113 (FIG. 1) was formed on the surface 411 to prepare a sample defined as a sample 1.

On the other hand, another cemented carbide planar body (specimen 41) made of the same material but having no modified surface layer formed thereon was prepared for comparison as a sample 2.

The friction coefficients of the specimens 41 (the sample 1 and the sample 2) were measured using an abrasion and friction tester (HEIDON (trade name) manufactured by SHINTO Scientific Co., Ltd.) , and the abrasion resistances thereof were evaluated.

A test method using the abrasion and friction tester will be described with reference to an image view shown in FIG. 12. As shown in FIG. 12, an indenter ball 42 having a diameter of 10 mm and made of silicon carbide is linearly slid by a distance of 6 mm (an arrow M) while the indenter ball 42 was pressed against the surface 411 of the specimen 41 under a load of 100 g (0.98 N) (an arrow F). At this time, the indenter ball 42 does not roll, so is always brought into contact with the specimen 41 at the same position of a spherical surface thereof. The sliding was reciprocated 1,000 times to measure the friction coefficients.

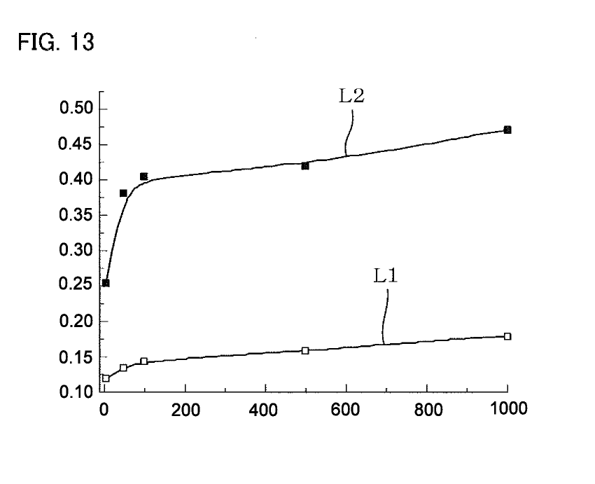

FIG. 13 shows measurement results of the friction coefficients of the samples 1 and 2. In FIG. 13, a curve L1 represents the result of the sample 1, and a curve L2 represents the result of the sample 2. Herein, the friction coefficients at the time of being reciprocated 5 times, 50 times, 100 times, 500 times and 1,000 times are plotted. These plotted points are connected by the curves L1 and L2. The friction coefficient at each plotted point represents an average of the friction coefficients of the sample continuously reciprocated 5 times until the plotted time. That is, for example, the friction coefficient at the time of being reciprocated 5 times represents an average value calculated from the friction coefficients of the first reciprocating to the fifth reciprocating. The friction coefficient at the time of being reciprocated 500 times represents an average value calculated from the friction coefficients of the 496th reciprocating to the 500th reciprocating.

As can be seen from FIG. 13, as the number of times of sliding is increased, the friction coefficient of each of the samples is gradually increased. However, the friction coefficient (L1) of the sample 1 is significantly low as compared with the friction coefficient (L2) of the sample 2. That is, it is considered that since the sample 1, as an embodiment of the present invention, has a friction coefficient so small with respect to silicon carbide, the friction resistance against the silicon carbide is reduced and abrasion can be decelerated in the sample 1.

The abrasive flaw of the indenter ball 42 reciprocatably slid 1,000 times and further reciprocatably slid 20,000 times was observed. Herein, not the abrasive flaw of the specimen 41 but the abrasive flaw of the indenter ball 42 was observed. The reason was as follows. The hardness of the cemented carbide was so high to observe the condition of abrasion, so the abrasion degree of the specimen 41 is indirectly assessed by the abrasive flaw of the indenter ball 42. That is, it is considered that as the abrasive flaw of the indenter ball 42 is greater, the specimen 41 can be evaluated to have higher abrasion resistance and lower abrasion degree in relation to the friction coefficient with respect to the indenter ball 42. Conversely, it is considered that as the abrasive flaw of the indenter ball 42 is smaller, the specimen 41 can be evaluated to have lower abrasion resistance and higher abrasion degree in relation to the friction coefficient with respect to the indenter ball 42.

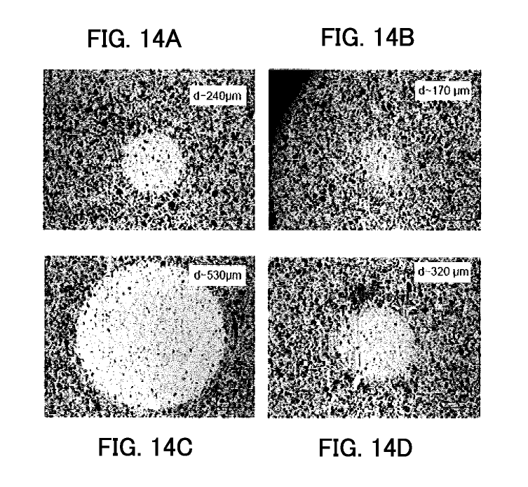

FIG. 14 shows the SEM photograph of the abrasive flaw of the indenter ball 42 obtained by the test. FIG. 14(A) shows the abrasive flaw of the indenter ball reciprocatably slid 1,000 times on the sample 1. FIG. 14(B) shows the abrasive flaw of the indenter ball reciprocatably slid 20,000 times on the sample 1. FIG. 14(C) shows the abrasive flaw of the indenter ball reciprocatably slid 1,000 times on the sample 2. FIG. 14(D) shows the abrasive flaw of the indenter ball reciprocatably slid 20,000 times on the sample 2. In each of FIGS. 14 (A) to 14 (D) , a comparatively white portion having a substantially circular shape represents the abrasive flaw.

As can be seen from FIG. 14, in both the sample 1 and the sample 2, the abrasive flaw at the time of being reciprocated 20,000 times is certainly larger than that at the time of being reciprocated 1,000 times. However, the diameter of the abrasive flaw of the indenter ball 42 used for the sample 2 was 170 μm at the time of being reciprocated 1,000 times, and 320 μm at the time of being reciprocated 20,000 times. On the other hand, the diameter of the abrasive flaw of the indenter ball 42 used for the sample 1 was a large size of 240 μm at the time of being reciprocated 1,000 times and 530 μm at the time of being reciprocated 20,000 times. That is, at the time of being reciprocated 20,000 times, the diameter of the abrasive flaw of the indenter ball 42 used for the sample 1 as the product according to the embodiment of the present invention was 2.75 times larger than that of the abrasive flaw of the indenter ball 42 used for the sample 2 as a comparison product.

The result shows that the abrasion resistance of the sample 1 is sufficiently larger than that of the sample 2, and an embodiment of the present invention can easily provide the die having excellent abrasion resistance.

In the examples described above, the surface of the die was modified. However, other embodiment of the present invention can be also applied to various superhard members having a surface on which the particles having hardness higher than that of tungsten carbide slide. For example, the embodiment of the present invention can be applied to various members such as a nozzle member supplying a paste containing silicon carbide particles, a piping member through which the paste passes, a member forming an inner wall of an extrusion molding machine, and a blade member for transferring or stirring the paste.

In the examples described above, the copper was gasified by the electron beam. However, the gasifying method is not restricted to the electron beam. A resistance heating system, a high-frequency induction system and a laser system or the like may be used.

Furthermore, a pressure-reduced atmosphere is desirably about about 10⁻³ to about 10⁻⁴ Pa.

Obviously, numerous modifications and variations of the present invention are possible in light of the above teachings. It is therefore to be understood that within the scope of the appended claims, the invention may be practiced otherwise than as specifically described herein.

1. A die comprising:
a base body including tungsten carbide particles bonded by a bonding phase; and
a modified surface layer including tungsten carbide particles and a filling material filled among the tungsten carbide particles to bond the tungsten carbide particles to each other, the filling material comprising copper, the modified surface layer being formed on at least a part of a surface of the base body.

2. The die according to claim 1, wherein a depth of the modified surface layer is equal to or greater than an average particle diameter of the tungsten carbide particles.

3. The die according to claim 1, wherein a depth of the modified surface layer is about 1 to about 10 μm.

4. The die according to claim. 1, wherein the modified surface layer has a superficial layer opposite to the base body, each of the tungsten carbide particles disposed in the superficial layer is covered with a surface layer including copper.

5. The die according to claim 4, wherein a thickness of the surface layer is about 0.1 to about 10 μm.

6. The die according to claim 1, wherein the modified surface layer is formed by bringing vaporized copper into contact with a surface of the die and making the vaporized copper penetrate among the tungsten carbide particles in a pressure-reduced atmosphere.

7. The die according to claim 1, wherein the modified surface layer is formed on at least a surface of the die on which a high hardness particle-containing material slides, to mold the high hardness particle-containing material including particles having hardness higher than hardness of the tungsten carbide particles.

8. The die according to claim 7, wherein the high hardness particle-containing material comprises a paste containing silicon carbide particles.

9. The die according to claim 1, wherein the die is so constructed to be used for extrusion molding of a honeycomb body having dividing walls to define cells, and wherein the die has slits to mold the passed material to the dividing walls.

10. The die according to claim 1, wherein the modified surface layer is formed on a whole surface of the base body.

11. The die according to claim 1, wherein an average particle diameter of the tungsten carbide particles is about 1 μm.

12. The die according to claim 9, wherein the honeycomb body includes silicon carbide.

13. The die according to claim 1, wherein the base body includes the tungsten carbide particles bonded by the bonding phase made of cobalt.

14. A method for manufacturing the die according to claim 1, comprising:
etching at least a part of a surface of a cemented carbide including tungsten carbide particles bonded by a bonding phase with acid to form an etched surface with a part of the bonding phase removed;
gasifying copper in a chamber of a pressure-reduced atmosphere in which the cemented carbide is disposed; and
liquefying gasified copper on the etched surface in the chamber to impregnate grain boundaries of the tungsten carbide particles with liquefied copper.

15. The method for manufacturing the die according to claim 14, further comprising:
treating the etched surface with an alkali solution between the etching step and the liquefying step to remove an oxide attached to the tungsten carbide particles.

16. The method according to claim 14, wherein a depth of the modified surface layer is equal to or greater than an average particle diameter of the tungsten carbide particles.

17. The method according to claim 14, wherein a depth of the modified surface layer is about 1 to about 10 μm.

18. The method according to claim 14, wherein the modified surface layer has a superficial layer opposite to the base body, each of the tungsten carbide particles disposed in the superficial layer is covered with a surface layer including copper.

19. The method according to claim 18, wherein a thickness of the surface layer is about 0.1 to about 10 μm.

20. The method according to claim 14, wherein the modified surface layer is formed by bringing vaporized copper into contact with a surface of the die and making the vaporized copper penetrate among the tungsten carbide particles in a pressure-reduced atmosphere.

21. The method according to claim 14, wherein the modified surface layer is formed on at least a surface of the die on which a high hardness particle-containing material slides, to mold the high hardness particle-containing material including particles having hardness higher than hardness of the tungsten carbide particles.

22. The method according to claim 21, wherein the high hardness particle-containing material comprises a paste containing silicon carbide particles.

23. The method according to claim 14, wherein the die is so constructed to be used for extrusion molding of a honeycomb body having dividing walls to define cells, and wherein the die has slits to mold the passed material to the dividing walls.

24. The method according to claim 14, wherein the modified surface layer is formed on a whole surface of the base body.

25. The method according to claim 14, wherein an average particle diameter of the tungsten carbide particles is about 1 ᵢ.tm.

26. The method according to claim 23, wherein the honeycomb body includes silicon carbide.

27. The method according to claim 14, wherein the base body includes the tungsten carbide particles bonded by the bonding phase made of cobalt.

28. The method according to claim 14, wherein the gasifying step is performed by means of an electron beam, a resistance heating system, a high-frequency induction system or a laser system.

29. The method according to claim 14, wherein the pressure-reduced atmosphere is about 10⁻³ to about 10⁻⁴ Pa.

30. The method according to claim 14, wherein a removal depth of the bonding phase in the etching step is about 5 to about 7 μm.
